(19) United States
(12) Patent Application Publication
(10) Pub. No.: US 2026/0310027 A1
(43) Pub. Date: Oct. 8, 2026

(54) INSERT MOLD, DISPLAY MODULE, AND DISPLAY DEVICE AND METHOD FOR MANUFACTURING THE SAME

(71) Applicants: Wuhan Tianma Microelectronics Co., Ltd. Shanghai Branch, Shanghai (CN); Wuhan Tianma Microelectronics Co., Ltd., Wuhan (CN)

(72) Inventors: Fengjuan HUANG, Shanghai (CN); Mingyan Huang, Shanghai (CN)

(73) Assignees: Wuhan Tianma Microelectronics Co., Ltd. Shanghai Branch, Shanghai (CN); Wuhan Tianma Microelectronics Co., Ltd., Wuhai (CN)

(21) Appl. No.: 19/635,861

(22) Filed: Apr. 1, 2026

(30) Foreign Application Priority Data
Apr. 2, 2025 (CN) 202510413930.8

(51) Int. Cl. G02F 1/1339; G02F 1/1333; H10K 59/12; H10K 59/80

(52) U.S. Cl. CPC G02F 1/1339; G02F 1/13332; H10K 59/1201; H10K 59/8722

(57) ABSTRACT

An insert mold, a display module, and a display device and a method for manufacturing the same are provided. The insert mold includes a first mold. The first mold includes a first mold core and a first mold base provided outside the first mold core. The first mold core has first and second surfaces opposite to each other in a first direction. The first surface is configured to contact the display module. The first mold core includes an injection channel and a cavity recessed from the first surface and separated from each other. The cavity is configured to form a dam structure through injection. The first mold core includes a fixing structure in contact with the dam structure, so that the insert mold is configured to take the dam structure away from the display module through the fixing structure.

### CROSS-REFERENCE TO RELATED APPLICATION

This application claims priority to Chinese Patent Application No. 202510413930.8, filed on Apr. 2, 2025, which is hereby incorporated by reference in its entirety.

### TECHNICAL FIELD

The present disclosure relates to the technical field of display devices, and in particular to an insert mold, a display module, and a display device and a method for manufacturing the same.

### BACKGROUND

With the development of science and technology, the field of display panels has also witnessed a great progress, and people have increasing demands for narrow bezel. With the insert molding technology, the middle frame is bonded with the plastic frame, which narrows the bezel of the display device and can also enhance the structural strength of the display module in the display device. However, how to reduce the impact of the insert molding technology on the structure of the finally formed display device is still a technical problem that needs to be solved.

### SUMMARY

In a first aspect, embodiments of the present disclosure provide an insert mold for forming a plastic frame on a display module. The insert mold includes a first mold, and the first mold includes a first mold core and a first mold base provided outside the first mold core. The first mold core has a first surface and a second surface opposite to each other in a first direction, and the first surface is configured to be in contact with the display module. The first mold core includes an injection channel, a cavity, and a fixing structure. The injection channel and the cavity are recessed from the first surface and separated from each other. The cavity is configured to form a dam structure through injection. The fixing structure is configured to be in contact with the dam structure so that the insert mold is configured to take the dam structure away from the display module through the fixing structure.

In a second aspect, embodiments of the present disclosure provide a display module. The display module is attached to a plastic frame through the insert mold provided in any one of the above embodiments. The display module includes a display portion, a cover plate, a composite functional layer, and an adhesion-reducing layer. The cover plate is provided on a side of the display portion, the composite functional layer is provided on a side of the display portion away from the cover plate, and the adhesion-reducing layer is provided on a side of the composite functional layer away from the display portion and has adhesion smaller than adhesion of at least one layer of the composite functional layer.

In a third aspect, embodiments of the present disclosure provide a display module. The display module includes a display portion, a cover plate, a binding portion, a protective layer, and an adhesive layer. The cover plate is provided on a side of the display portion, the binding portion is provided on a side of the display portion away from the cover plate, and the protective layer is provided on a side of the binding portion away from the display portion. The binding portion extends beyond the protective layer in a third direction to form a step structure, and a thickness direction of the display portion intersects with the third direction. The adhesive layer is partially provided between the binding portion and the protective layer, and a part of the adhesive layer is attached to the step structure.

In a fourth aspect, embodiments of the present disclosure provide a display device, which is manufactured using the insert mold provided in any one of the above embodiments. The display device includes a display module and a plastic frame that is provided on a periphery of the display module. The display device does not include the dam structure.

In a fifth aspect, embodiments of the present disclosure provide a method for manufacturing a display device. The method includes: attaching the first mold core of the insert mold provided in any one of the above embodiments to the display module, the cavity penetrating through the first mold core along the first direction; forming the dam structure in the cavity; forming the plastic frame in the injection channel; and separating the first mold core together with the dam structure from the display module.

### BRIEF DESCRIPTION OF THE DRAWINGS

In order to more clearly illustrate the technical solution of the embodiments of the present disclosure, the following will briefly introduce the drawings use in the embodiments of the present disclosure. For those skilled in the art, other drawings can be obtained based on these drawings.

FIG. 1 is a schematic diagram of assembly of a display module and an insert mold provided in some embodiments of the present disclosure;

FIG. 2 is a schematic diagram of assembly of a display module and a first mold core provided in some embodiments of the present disclosure;

FIG. 3 is another schematic diagram of assembly of a display module and a first mold core provided in some embodiments of the present disclosure;

FIG. 4 is another schematic diagram of assembly of a display module and a first mold core provided in some embodiments of the present disclosure;

FIG. 5 is another schematic diagram of assembly of a display module and a first mold core provided in some embodiments of the present disclosure;

FIG. 6 is a another schematic diagram of assembly of a display module and a first mold core provided in some embodiments of the present disclosure;

FIG. 7 is a schematic diagram of enlarged structures in a region Q in FIG. 6;

FIG. 8 is a schematic diagram of a display module provided in some embodiments of the present disclosure;

FIG. 9 is a schematic diagram of partial assembly of a display module and a first mold core provided in some embodiments of the present disclosure;

FIG. 10 is another schematic diagram of a display module provided in some embodiments of the present disclosure;

FIG. 11 is another schematic diagram of a display module provided in some embodiments of the present disclosure;

FIG. 12 is a schematic diagram of a display device provided in some embodiments of the present disclosure;

FIG. 13 is a flow chart of a method for manufacturing a display device provided in some embodiments of the present disclosure; and

FIGS. 14A-14D are process diagrams of a method for manufacturing a display device provided in some embodiments of the present disclosure.

### REFERENCE NUMERALS

100, insert mold; 200, display module; 300, display device;

J1, first mold; J11, first mold base; J2, second mold; J21, second mold base; J22, second mold core;

10, first mold core; 11, first surface; 111, first sub-surface; 112, second sub-surface; 12, second surface; 13, cavity; 131, first sub-cavity; 132, second sub-cavity; 133, side wall; 134, first opening; 135, second opening; 14, injection channel; 15, fixing structure; 151, protruding structure; 152, support surface; 153, bonding layer; 16, resin injecting channel;

20, dam structure; 21, first sub-portion; 22, second sub-portion;

31, display portion; 32, cover plate; 33, composite functional layer; 331, binding portion; 332, protective layer; 333, support layer; 34, adhesion-reducing layer; 35, bending portion; 36, adhesive layer; 361, overflow portion;

40, plastic frame;

T, step structure;

X1, first direction; Y1, second direction; X2, thickness direction; Y2, third direction; Z, fourth direction.

### DETAILED DESCRIPTION

Features and exemplary embodiments of various aspects of the present disclosure will be described in detail below. In order to make the purpose, technical solutions and advantages of the present disclosure more clear, the present disclosure will be described in detail below in conjunction with the accompanying drawings and specific embodiments. It should be understood that the specific embodiments described here are only intended to explain the present disclosure, rather than limiting the present disclosure. For those skilled in the art, the present disclosure can be implemented without some of these specific details. The following description of the embodiments is only to provide a better understanding of the present disclosure by illustrating the example of the present disclosure.

It should be noted that, in the present disclosure, relational terms such as first and second, etc. are only used to distinguish one entity or operation from another entity or operation, and do not necessarily require or imply any such actual relationship or order between these entities or operations. Moreover, the terms "comprise", "contain" or any other variants thereof are intended to cover non-exclusive inclusion, so that a process, method, article, or device including a series of elements comprises not only those elements, but also other elements not explicitly listed, or also comprises elements inherent to such process, method, article or device. Without any further limitations, the elements defined by the phrase "including..." do not exclude that the process, method, article, or apparatus including the element includes an additional element identical to the element.

The display module 200 is configured to manufacture the display device 300 and has a display region, a binding region, and a bending region between the display region and the binding region. In a process of manufacturing the display device 300, the bending region usually is bent. In this process, due to the influence of factors such as a thickness of the layer itself, a part of a layer structure in the display region will shrink relative to another layer, thereby forming a step structure T at a boundary.

During the assembly process of the insert mold 100 and the display module 200, with the step structure T, a poor assembly easily occurs between the insert mold 100 and the display module 200, resulting in a risk of air leakage at the boundary. In some embodiments, during the insert molding process, due to air leakage, poor molding of the plastic frame 40 easily occurs, reducing the yield rate and reliability of the finally formed display device 300.

In order to improve the air leakage, a dam can be added at an edge of the display module 200 to block the air leakage channel. However, the dam becomes useless after the insert molding, and the dam will occupy the space for the entire device of the display device 300, which is not conducive to the internal structure layout of the display device 300.

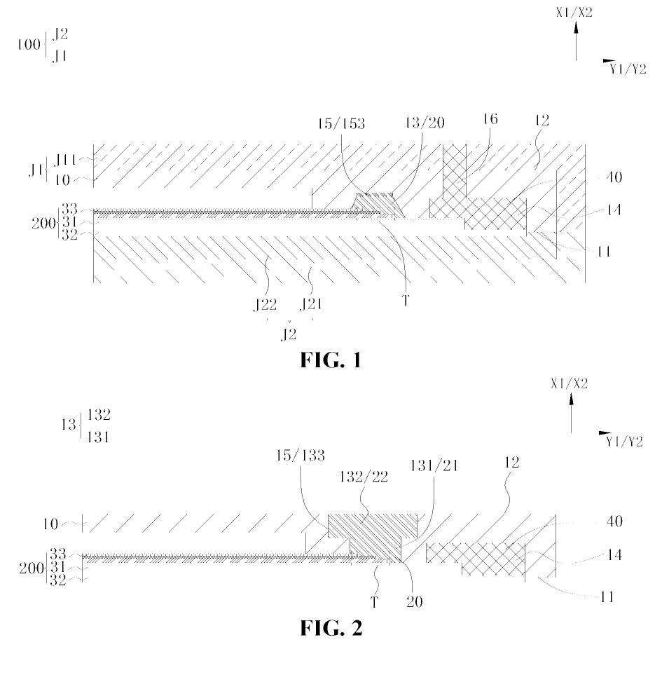

To solve the above problem, in a first aspect, please referring to FIG. 1, some embodiments of the present disclosure provide an insert mold 100 used to form a plastic frame 40 on the display module 200. The insert mold 100 includes a first mold J1 and a second mold J2. The first mold J1 includes a first mold core 10 and a first mold base J11 provided outside the first mold core 10. The second mold J2 includes a second mold core J22 and a second mold base J21 provided outside of the second mold core J22.

The first mold core 10 has a first surface 11 and a second surface 12 opposite to each other in a first direction X1, the first surface 11 is configured to contact the display module 200, and the first mold core 10 includes an injection channel 14 and a cavity 13 that are recessed from the first surface 11 and that are separated from each other. The cavity 13 is configured to form the dam structure 20 through injection, the first mold core 10 includes a fixing structure 15 configured to be in contact with the dam structure 20, and the insert mold 100 takes the dam structure 20 away from the display module 200 through the fixing structure 15.

The insert mold 100 is a processing tool for forming the plastic frame 40. Specifically, the insert mold 100 is used for insert molding on a periphery of the display module 200, so as to form the plastic frame 40 on an outer periphery of the display module 200. The plastic frame 40 is configured to connect to a middle frame located on an outer periphery of the plastic frame 40 to achieve a relative fixation between the display module 200 and the middle frame. The plastic frame 40 is also configured to support and protect the internal structure of the display module 200.

The insert mold 100 includes the first mold J1 and the second mold J2. During the insert molding process, the first mold J1 and the second mold J2 are first assembled in association with the display module 200, and then resin is casted into the injection channel 14 to form the plastic frame 40 fixed to the display module 200. After that, the first mold J1 and the second mold J2 are moved away from the display module 200 to separate the display module 200 from the insert mold 100.

The first mold J1 includes a first mold core 10 and a first mold base J11, and the second mold J2 includes a second mold core J22 and a second mold base J21. The first mold core 10 and the second mold core J22 are core components of the first mold J1 and the second mold J2, respectively, and are provided at two sides of the display module 200 in a thickness direction X2 and both abut against the display module 200. The first mold base J11 and the second mold base J21 are basic structures of the first mold J1 and the second mold J2, respectively, and play roles of supporting and fixing corresponding mold cores.

In some optional embodiments, the first mold core 10 and the second mold core J22 include flexible materials, and the first mold base J11 and the second mold base J21 include rigid materials. Optionally, the first mold core 10 and the second mold core J22 include silicone materials, the first mold base J11 and the second mold base J21 include metal materials, and the first mold core 10 and the second mold core J22 are formed by overmolding on the first mold base J11 and the second mold base J21, respectively.

The first mold core 10 has a first surface 11 and a second surface 12 opposite to each other in the first direction X1. After the first mold core 10 and the display module 200 are assembled together, the first direction X1 can be parallel to the thickness direction X2 of the display module 200, and the first surface 11 can be in direct contact with the display module 200. The injection channel 14 is recessed inward from the first surface 11, and a size and a shape of the injection channel 14 determine a size and a shape of the plastic frame 40, respectively. The size and the shape of the injection channel 14 are generally related to a size and a shape of the display module 200, respectively, which are not limited in the embodiments of the present disclosure. Optionally, the display module 200 can be circular or rectangular. Accordingly, the injection channel 14 can be an annular injection channel 14 surrounding the circular display module 200, or a rectangular frame injection cavity channel surrounding the rectangular display module 200.

In order to meet the needs of casting resin, the first mold core 10 is provided with a resin injecting channel and a resin outlet channel, both of which are located at a side of the injection channel 14 facing towards the second surface 12, are in communication with the injection channel 14, and are separated from each other. Correspondingly, the first mold base J11 is provided with a resin inlet in communication with the resin injecting channel and a resin outlet in communication with the resin outlet channel. The specific positions of the resin injecting channel and the resin outlet channel are not limited in the embodiments of the present disclosure. FIG. 1 shows a case where the resin injecting channel 16 is located at a side of the step structure T of the display module 200, while FIG. 2 shows a case where neither the resin injecting channel nor the resin outlet channel is located at the side of the step structure T.

In addition to the injection channel 14, the first mold core 10 is provided with a cavity 13 that is a cavity structure in the first mold core 10 for forming a dam structure 20 through injection. The dam structure 20 is a blocking structure and is provided at the step structure T to block the air leakage space during the insert molding process, thereby improving the structural reliability of the plastic frame 40. Similar to the injection channel 14, the cavity 13 is also recessed inward from the first surface 11. The injection channel 14 is separated from the cavity 13, and during the insert molding process, the injection channel 14 and the cavity 13 are insulated from each other, that is, the resin casted into the injection channel 14 will not enter the cavity 13.

In the related art, a dam and the insert mold 100 are usually two independent structures. Usually, the dam is first provided on the display module 200, and then the display module 200 with the dam is assembled with the insert mold 100. However, in the embodiments of the present disclosure, the insert mold 100 is configured to form the dam structure 20 in addition to the plastic frame 40. Specifically, the cavity 13 of the first mold core 10 in the insert mold 100 is configured to form the dam structure 20 through injection, that is, the dam structure 20 is formed by using the insert mold 100. During the insert molding process, it is necessary to first form the dam structure 20 in the cavity 13 through injection, and then perform the resin casting process. The injection molding methods in the related art and the embodiments of the present disclosure are different from each other.

According to different actual needs, the dam structure 20 can be formed in the insert mold 100 first, and then the insert mold 100 and the dam structure 20 can be assembled together in the display module 200; or the insert mold 100 and the display module 200 can be assembled first, and then the dam structure 20 can be formed through injection, which is not limited in the embodiments of the present disclosure. A size and a shape of the dam structure 20 are determined by a size and a shape of the cavity 13, respectively. The specific shape and size of the cavity 13 are not limited in the embodiment of the present disclosure. The cavity 13 can penetrate through the first mold core 10, or the cavity 13 can also not penetrate through the first mold core 10.

The first mold core 10 includes the fixing structure 15 that can be in contact with the dam structure 20 formed through injection. During a process where the insert mold 100 is separated from the display module 200, the dam structure 20 can be taken by the fixing structure 15 to move away from the display module 200, thereby achieving relative separation from the display module 200, so that the finally formed display device 300 does not include the dam structure 20, thereby reducing the influence of the dam structure 20 on the internal structural layout of the display device 300.

It should be noted that the fixing structure 15 can be in various forms. For example, the fixing structure 15 includes a wall structure that is enclosed to form the cavity 13, that is, the shape of the cavity 13 can be adjusted so that the wall structure around the cavity 13 can drive the dam structure 20 away from the display module 200, or the fixing structure 15 can include other structures located in the cavity 13, which is not limited in the embodiments of the present disclosure as long as the fixing structure 15 is located on the first mold core 10 and can take the dam structure 20 to move together.

In some optional embodiments, as shown in FIG. 1, the cavity 13 does not penetrate through the first mold core 10 in the first direction X1, and the fixing structure 15 includes an adhesive layer 153 provided on a bottom wall of the cavity 13. The dam structure 20 formed in the cavity 13 can be fixed to the first mold core 10 through the adhesive layer 153, and after the insert molding, the dam structure 20 can be taken to move away from the display module 200 through the adhesive layer 153.

In summary, in the embodiments of the present disclosure, the structure of the first mold core 10 in the insert mold 100 is adjusted, so that the dam structure 20 can be formed through injection using the first mold core 10, thereby improving the structural fitting degree between the dam structure 20 and the first mold core 10, enhancing the effect that the dam structure 20 blocks the air leakage channel, and improving the structural reliability of the plastic frame 40. On such basis, the first mold core 10 is provided with the fixing structure 15. After the insert molding, the insert mold 100 takes the dam structure 20 away from the display module 200 through the fixing structure 15, so that no dam structure 20 is provided in the finally formed display device 300, reducing the effect of the dam structure 20 on the internal layout of the display device 300. In this way, the reliability of the plastic frame 40 is improved while the internal structure of the display device 300 is simplified, which frees up the space for the entire device.

In some embodiments, as shown in FIG. 2, the cavity 13 penetrates through the first mold core 10 in the first direction X1.

With reference to the above contents, it can be learned that, different from the related art, the first mold core 10 and the dam structure 20 in the embodiments of the present disclosure are not two independent structures, and the formation of the dam structure 20 through injection relies on the first mold core 10. In view of this, in order to improve the manufacturing accuracy of the dam structure 20 and enhance the fitting effect between the dam structure 20 and the step structure T, the cavity 13 is provided to penetrate through the first mold core 10 in some embodiments of the present disclosure.

Specifically, since the cavity 13 penetrates through the first mold core 10 along the first direction X1, during the insert molding process, the first mold core 10 and the display module 200 can be assembled together first, and then injection is performed from a side of the second surface 12 to the inside of the cavity 13 to form the dam structure 20. With such design, the size and the shape of the dam structure 20 is determined by not only the size and the shape of the cavity 13, but also the size and the shape of the display module 200, so that the surface of the dam structure 20 facing towards the display module 200 can better fit and is better attached to the step structure T, thereby reducing the risk of air leakage at the step structure T and improving the manufacturing reliability of the plastic frame 40.

In some embodiments, as shown in FIG. 2, the fixing structure 15 includes a side wall 133 of the cavity 13, and the cavity 13 includes a first sub-cavity 131 and a second sub-cavity 132 in communication with each other in the first direction X1, and the second sub-cavity 132 is located at a side of the first sub-cavity 131 facing towards the second surface 12. The maximum size of the second sub-cavity 132 in the second direction Y1 is greater than the maximum size of the first sub-cavity 131 in the second direction Y1, and the second direction Y1 is perpendicular to the first surface 11.

The first sub-cavity 131 and the second sub-cavity 132 are different components of the cavity 13, and are both configured to define and form the dam structure 20. In view of this, the dam structure 20 includes a first sub-portion 21 in the first sub-cavity 131 and a second sub-portion 22 in the second sub-cavity 132. The second sub-cavity 132 is located at a side of the first sub-cavity 131 facing towards the second surface 12, so the first sub-portion 21 is closer to the display module 200 than the second sub-portion 22. Optionally, the first sub-portion 21 is in contact with the step structure T.

Since the maximum size of the second sub-cavity 132 in the second direction Y1 is greater than the maximum size of the first sub-cavity 131 in the second direction Y1, the maximum size of the second sub-portion 22 in the second direction Y1 is greater than the maximum size of the first sub-portion 21 in the second direction Y1. The second direction Y1 mentioned here refers to any direction perpendicular to the first direction X1. In other words, it is sufficient that the maximum size of the second sub-cavity 132 in any direction perpendicular to the first direction X1 is greater than the maximum size of the first sub-cavity 131.

With such design, when the first mold core 10 is moving away from the display module 200, due to the difference in the maximum sizes of the first sub-cavity 131 and the second sub-cavity 132 in the second direction Y1, the second sub-portion 22 will be supported by the side wall 133 of the cavity 13, thereby causing the dam structure 20 to move away from the display module 200, so that the dam structure 20 is not provided in the finally formed display device 300, thereby reducing the effect of the dam structure 20 on the internal layout of the display device 300 and freeing up space for the entire device.

The sizes and the shapes of the first sub-cavity 131 and the second sub-cavity 132 are not limited in the embodiments of the present disclosure. At different positions in the first direction X1, the first sub-cavity 131 can have a same size in the second direction Y1, or can have different sizes in the second direction Y1, and the second sub-cavity 132 is similar to the first sub-cavity 131. Optionally, as shown in FIG. 2, the side wall 133 of the first sub-cavity 131 can be separated from the side wall 133 of the second sub-cavity 132, the first sub-cavity 131 at different positions has a same size in the second direction Y1, and the second sub-cavity 132 at different positions has a same size in the second direction Y1. In view of this, the side wall 133 of the cavity 13 includes a first wall surface located on a periphery of the first sub-cavity 131, a second wall surface located on a periphery of the second sub-cavity 132, and a connecting wall connecting the first wall surface and the second wall surface. In this case, when the first mold core 10 moves away from the display module 200, the connecting wall can lift and takes the dam structure 20 to move away from the display module 200.

In some embodiments, the first sub-cavity 131 and the second sub-cavity 132 can have a same shape or different shapes. For example, a projection of the first sub-cavity 131 in the first direction X1 is circular, and a projection of the second sub-cavity 132 in the first direction X1 is square, or the projections of the first sub-cavity 131 and the second sub-cavity 132 in the first direction X1 each can be circular. In addition to the first sub-cavity 131 and the second sub-cavity 132, the cavity 13 can include other sub-cavity structures, or can include no other sub-cavity structures, which is not limited in the embodiments of the present disclosure.

In the embodiments of the present disclosure, the first sub-cavity 131 and the second sub-cavity 132 in the cavity 13 have different maximum sizes in the second direction Y1, so that the dam structure 20 can be supported by the side wall 133 of the cavity 13 when the first mold core 10 is separated from the display module 200, thereby meeting the separation requirements between the dam structure 20 and the display module 200 and freeing up space for the entire device.

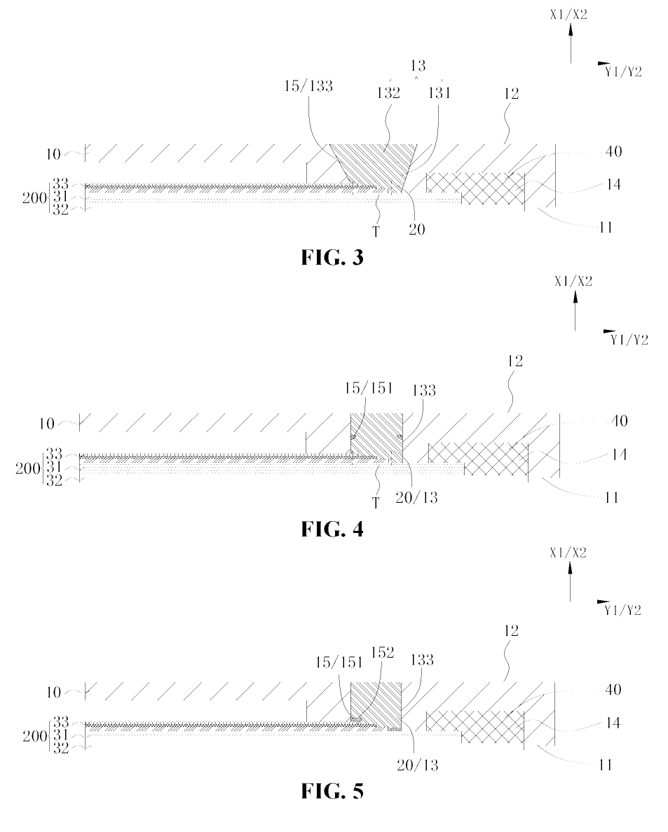

In some embodiments, referring to FIG. 3, the size of the cavity 13 in the second direction Y1 gradually increases in a direction from the first surface 11 to the second surface 12.

Since the size of the cavity 13 in the second direction Y1 gradually increases in the direction gradually approaching the second surface 12, the maximum size of the first sub-cavity 131 in the second direction Y1 is a size of an end of the first sub-cavity 131 close to the second sub-cavity 132 in the second direction Y1, and the maximum size of the second sub-cavity 132 in the second direction Y1 is a size of an end of the second sub-cavity 132 away from the first sub-cavity 131 in the second direction Y1. Optionally, the side wall 133 of the first sub-cavity 131 and the side wall 133 of the second sub-cavity 132 are continuously connected with each other, and together form an inclined surface structure provided around the dam structure 20.

In the embodiments of the present disclosure, the size of the cavity 13 in the second direction Y1 gradually increases, so that the side wall 133 of the cavity 13 can be a smooth and continuous inclined structure. In this way, when the first mold core 10 is separated from the display module 200, the side wall 133 of the cavity 13 can lift the dam structure 20 to move away from the display module 200 together with the first mold core 10. In view of this, the structure of the relatively smooth side wall 133 can enhance the attachment of the side wall 133 to the dam structure 20, enhance the relative force between the side wall 133 and the dam structure 20, and reduce the risk of the dam structure 20 moving relative to the first mold core 10.

Since the side wall 133 of the cavity 13 can be a smooth and continuous inclined structure, during the manufacturing of the first mold core 10, the cavity 13 can be manufactured with a single process, thereby reducing the processing difficulty of the insert mold 100.

In some embodiments, the embodiments of the present disclosure can set sizes of two openings of the cavity 13 in the first direction X1 to be different from each other. Specifically, a size of the opening of the cavity 13 facing towards the display module 200 is smaller, and the size of this opening generally determines a contact area between the dam structure 20 and the display module 200. Therefore, such design can reduce the contact area between the dam structure 20 and the display module 200, which makes the dam structure 20 be more easily separated from the display module 200.

In some embodiments, referring to FIG. 4, the fixing structure 15 includes a protruding structure 151 protruding from the side wall 133 of the cavity 13, and the protruding structure 151 is configured to be in contact with the dam structure 20.

The protruding structure 151 is a structure protruding from the side wall 133 of the cavity 13. The protruding structure 151 and the side wall 133 of the cavity 13 can include same material and be formed together in a same manufacturing process. Alternatively, the protruding structure 151 can include a different material from the side wall 133 of the cavity 13 and be connected to the side wall 133 of the cavity 13 by welding or threaded connection.

In the embodiments of the present disclosure, the fixing structure 15 includes the protruding structure 151 that can fit and is in contact with the dam structure 20, so that when the first mold core 10 is separated from the module, the protruding structure 151 can directly or auxiliary take the dam structure 20 away from the display module 200, thereby meeting the separation requirements between the dam structure 20 and the display module 200 and freeing up space for the entire device.

It should be noted that the specific positional relationship between the protruding structure 151 and the dam structure 20, as well as the specific contact and connection method therebetween, is not limited in the embodiments of the present disclosure, as long as the protruding structure 151 can provide a certain demoulding force to the dam structure 20 to assist or directly achieve the relative separation between the dam structure 20 and the display module 200 during the process where the first mold core 10 is separated from the module. In some embodiments, only one protruding structure 151 can be provided in the cavity 13, or multiple protruding structures 151 can be provided in the cavity 13, which is not limited in the embodiments of the present disclosure.

In some embodiments, referring to FIGS. 4 and 5, at least part of the protruding structure 151 is configured to be in a plug-type fit with the dam structure 20. Alternatively, the protruding structure 151 includes a support surface 152 facing away from the first surface 11, and the support surface 152 is located in the cavity 13 and is separated from the second surface 12 in the first direction X1.

Since the protruding structure 151 protrudes from the inner wall of the cavity 13 and the dam structure 20 is formed by defining of the cavity 13, the protruding structure 151 will also affect the morphology of the dam structure 20. In view of this, the protruding structure 151 and the dam structure 20 can have different fitting relationships by setting the size and the shape of the protruding structure 151 and a position relative of the protruding structure 151 to the cavity 13.

Specifically, as shown in FIG. 4, if the protruding structure 151 is provided at a center of the side wall 133 of the cavity 13 in the first direction X1, the correspondingly formed dam structure 20 will have a groove structure corresponding to the protruding structure 151, and the protruding structure 151 can be in a plug-type fit with the dam structure 20 through the groove structure. With plug-type fit, the protruding structure 151 can provide a certain demoulding force to the dam structure 20, so as to directly or auxiliary take the dam structure 20 away from the display module 200 when the first mold core 10 is separated from the display module 200.

Alternatively, as shown in FIG. 5, if the protruding structure 151 has a certain size in the second direction Y1, and the support surface 152 of the protruding structure 151 away from the first surface 11 can be separated from the second surface 12, then the support surface 152 can provide a certain supporting force to the dam structure 20, and under the action of this supporting force, the protruding structure 151 can directly or auxiliary take the dam structure 20 away from the display module 200.

In summary, in the embodiments of the present disclosure, no matter in the plug-type fit with the dam structure 20 or having a support surface 152 for supporting the dam structure 20, the protruding structure 151 can provide a certain force to the dam structure 20 to directly or auxiliary take the dam structure 20 away from the display module 200, thereby reducing the effect of the dam structure 20 on the layout of the subsequently formed display device 300 and freeing up space for the entire device.

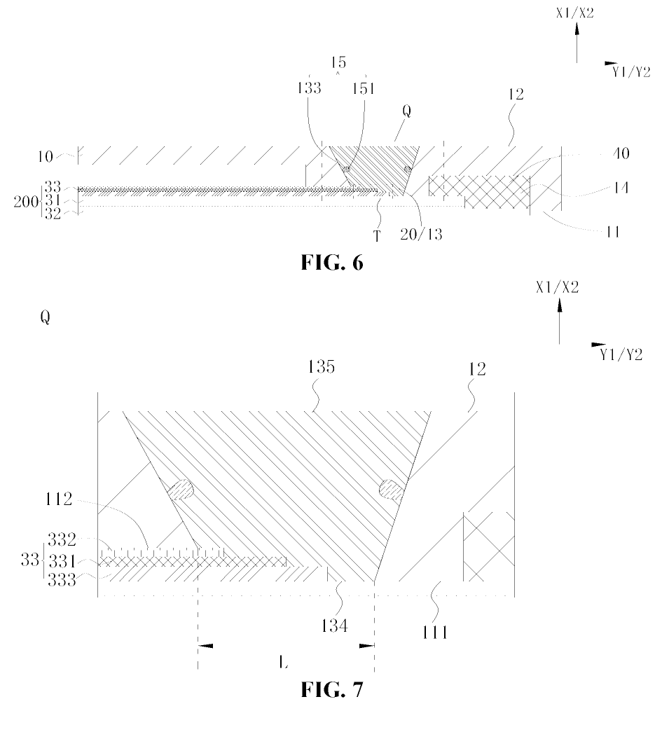

In some optional embodiments, referring to FIG. 6, the fixing structure 15 includes a side wall 133 of the cavity 13 and a protruding structure 151 protrusively connected to the side wall 133 of the cavity 13, and a size of the cavity 13 in the second direction Y1 gradually increases in the direction from the first surface 11 to the second surface 12. The protruding structure 151 is configured to be in the plug-type fit with the dam structure 20.

With such design, the dam structure 20 can be taken away from the display module 200 under the support of the side wall 133 of the cavity 13, and the protruding structure 151 can provide a certain demoulding force to the dam structure 20 to assist the dam structure 20 to separate from the display module 200.

In some embodiments, referring to FIGS. 6 and 7, the cavity 13 has a first opening 134 away from the second surface 12 in the first direction X1, a size L of the first opening 134 in the second direction Y1 satisfies: 0.2 mm ≤ L ≤ 2 mm, and the second direction Y1 is perpendicular to the first direction X1. Optionally, L is one of 0.2 mm, 0.3 mm, 0.5 mm, 0.8 mm, 1 mm, 1.5 mm, and 2 mm.

Taking the cavity 13 penetrating through the first mold core 10 along the first direction X1 as an example, the cavity 13 has a first opening 134 and a second opening 135 opposite to each other in the first direction X1. According to the different morphologies of the cavity 13 in different situations, the first opening 134 and the first opening 135 can have a same size or different sizes in the second direction Y1. The first opening 134 is farther away from the second surface 12 than the second opening 135, and the size of the first opening 134 is often positively correlated with a contact area between the dam structure 20 and the display module 200.

Therefore, in the embodiments of the present disclosure, the size L of the first opening 134 in the second direction Y1 is not greater than 2 mm, so as to limit and reduce the contact area between the dam structure 20 and the display module 200, thereby reducing the difficulty of separating the dam structure 20 from the display module 200 and improving the reliability of the insert molding process. At the same time, the size L of the first opening 134 in the second direction Y1 is not smaller than 0.2 mm, so that the dam structure 20 can cover the step structure T, thereby improving the blocking effect of the dam structure 20 on the air leakage channel, and improving the manufacturing yield of the plastic frame 40.

In some embodiments, as shown in FIGS. 6 and 7, the first surface 11 includes a first sub-surface 111 between the cavity 13 and the injection channel 14, and a second sub-surface 112 located at a side of the cavity 13 away from the injection channel 14. In the first direction X1, the second sub-surface 112 is located on a side of the first sub-surface 111 close to the second surface 12.

The first sub-surface 111 and the second sub-surface 112 are respectively located at two sides of the first opening 134 in the second direction Y1. Combined with the foregoing contents, it can be learned that when the first mold core 10 is assembled to the display module 200, the first opening 134 corresponds to the step structure T of the display module 200. With the step structure T, two areas of the display module 200 that are respectively in contact with the first sub-surface 111 and the second sub-surface 112 will be separated from each other in the thickness direction X2 of the display module 200.

In view of the above, the embodiments of the present disclosure set the first sub-surface 111 and the second sub-surface 112 to be separated from each other in the first direction X1, so that the first sub-surface 111 and the second sub-surface 112 respectively match the areas at two sides of the step structure T in the display module 200, thereby improving the assembly accuracy between the first mold core 10 and the display module 200, facilitating to improving the fit reliability between the dam structure 20 and the display module 200, and enhancing the sealing effect of the dam structure 20 on the leakage channel, thereby improving the manufacturing reliability of the plastic frame 40.

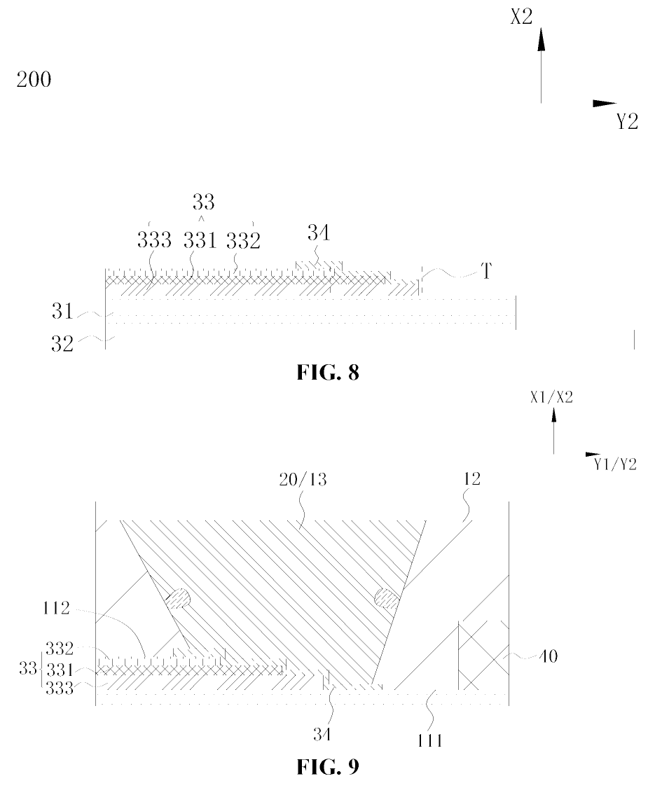

In a second aspect, referring to FIGS. 8 and 9, embodiments of the present disclosure provide a display module 200, which is attached to the plastic frame 40 through the insert mold 100 provided by any of the above embodiments. The display module 200 includes a display portion 31, a cover plate 32, a composite functional layer 33, and an adhesion-reducing layer 34. The cover plate 32 is provided on a side of the display portion 31, the composite functional layer 33 is provided on a side of the display portion 31 away from the cover plate 32, and the adhesion-reducing layer 34 is provided on a side of the composite functional layer 33 away from the display portion 31 and has adhesion smaller than adhesion of at least part of the layer in the composite functional layer 33.

The display module 200 is a core component of the display device 300, and the display portion 31 is a main component for realizing a display effect in the display module 200. The display portion 31 includes multiple stacked layer structures. For example, the display portion 31 can include an array substrate, a light-emitting functional layer, and a color filter substrate that are stacked together. Since the display device 300 can be in various types, the light-emitting functional layer can also be in various forms. Exemplarily, if the display device 300 is an organic light-emitting display device, the light-emitting functional layer includes a hole injection layer, an electron injection layer, and an organic light-emitting layer between the hole injection layer and the electron injection layer. If the display device 300 is a liquid crystal display device, the light-emitting functional layer includes a liquid crystal layer.

The display portion 31 has a light-emitting surface and a backlight surface opposite to each other in the thickness direction X2 of the display module 200. The cover plate 32 is a layer structure provided on a side of the light-emitting surface of the display portion 31 and configured to protect the display portion 31. The composite functional layer 33 is a layer structure provided on a side of the backlight surface of the display portion 31 and having a specific function. The specific function of the composite functional layer 33 is not limited in the embodiment of the present disclosure. Optionally, the composite functional layer 33 can have a function of supporting the display portion 31, or the composite functional layer 33 can also have a function of dissipating the heat generated during the operation of the display portion 31.

The composite functional layer 33 includes multiple stacked layer structures. During the bending process of the display module 200, due to the effect of factors such as the layer position and thickness, the multiple layer structures in the composite functional layer 33 will have different deformation amounts and form a step structure T at the edge. With the step structure T, an air leakage channel is easily formed during the insert molding process, reducing the manufacturing yield of the plastic frame 40.

However, in the embodiments of the present disclosure, the dam structure 20 is formed during the insert molding process, and can block the air leakage channel, thereby improving the manufacturing reliability of the plastic frame 40. At the same time, after the insert molding, the dam structure 20 can be separated from the display module 200 together with the insert mold 100, so that the dam structure 20 is not provided in the finally formed display device 300, releasing the space of the whole device.

In addition to the above layer structures, the display module 200 in the embodiments of the present disclosure includes an adhesion-reducing layer 34 provided on a side of the composite functional layer 33 away from the display portion 31. Therefore, during the formation process through injection, the adhesion-reducing layer 34 can replace the composite functional layer 33 to be directly contact the dam structure 20. Since the adhesion-reducing layer 34 has a lower adhesion than at least one layer in the composite functional layer 33, compared with the technical solution in which the dam structure 20 is in direct contact with the composite functional layer 33, such design can make it easier to separate the dam structure 20 from the display module 200, thereby reducing the space occupied by the dam structure 20 in the finally formed display device 300. At the same time, since a thickness of the adhesion-reducing layer 34 is generally smaller than the size of the dam structure 20 in the first direction X1, such design can reduce the difficulty in separating the dam structure 20 from the display module 200 while freeing up space for the entire device, and has a strong practicality.

It should be noted that the embodiments of the present disclosure do not limit the specific positional relationship between the adhesion-reducing layer 34 and the step structure T. The adhesion-reducing layer 34 can cover at least part of the step structure T, or can be offset from the step structure T, as long as the adhesion-reducing layer 34 can be in contact with the dam structure 20 during the insert molding process.

In some embodiments, as shown in FIGS. 8 and 9, a step structure T is formed in an edge region of a surface of the composite functional layer 33 away from the display portion 31 in a third direction Y2, and a thickness direction X2 of the display portion 31 intersects the third direction Y2. The adhesion-reducing layer 34 at least partially covers the step structure T.

The thickness direction X2 of the display portion 31 is a same direction as the thickness direction X2 of the display module 200. For the convenience of illustration, the embodiments of the present disclosure illustrate these two directions in the same direction. The third direction Y2 is a direction intersecting the thickness direction X2 of the display portion 31. Optionally, the third direction Y2 is perpendicular to the thickness direction X2 of the display portion 31. After the first mold core 10 and the display module 200 are assembled together, the first direction X1 is parallel to the thickness direction X2 of the display portion 31, and the second direction Y1 is parallel to the third direction Y2.

In the embodiments of the present disclosure, the step structure T is formed in the edge region of the composite functional layer 33 in the third direction Y2, and the adhesion-reducing layer 34 can at least partially cover the step structure T, thereby increasing a contact area between the adhesion-reducing layer 34 and the dam structure 20, and reducing the difficulty in separating the dam structure 20 from the display module 200.

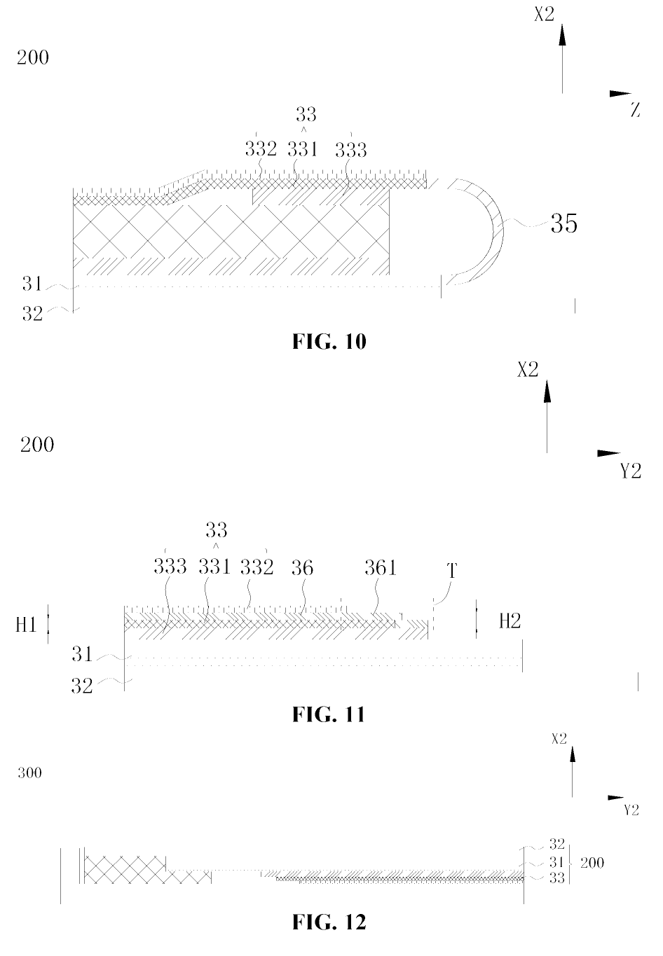

In some embodiments, referring to FIGS. 8-10, the composite functional layer 33 includes a binding portion 331 and a protective layer 332 provided on a side of the binding portion 331 away from the display portion 31. In the third direction Y2, the binding portion 331 extends beyond the protective layer 332 to form a step structure T. The display module 200 includes a bending portion 35. The binding portion 331 and the bending portion 35 are bent to a side of the display portion 31 away from the cover plate 32. An end of the display portion 31 along a fourth direction Z is connected to the bending portion 35. Any two of the thickness direction X2 of the display portion 31, the third direction Y2, and the fourth direction Z intersect each other.

The binding portion 331 is bent to the side of the display portion 31 away from the cover plate 32 through the bending portion 35, so that the display portion 31 and the binding portion 331 are opposite to each other in the thickness direction X2 of the display portion 31. The binding portion 331 and the display portion 31 are connected to each other through the bending portion 35, and an end of the binding portion 331 in the fourth direction Z and an end of the display portion 31 in the fourth direction Z are both connected to the bending portion 35. Optionally, any two of the thickness direction X2 of the display portion 31, the third direction Y2, and the fourth direction Z are perpendicular to each other.

The protective layer 332 is provided on a side of the binding portion 331 away from the display portion 31, and the protective layer 332 can protect the binding portion 331. Optionally, the protective layer 332 can include an insulating material, so that the protective layer 332 can not only achieve physical protection to the binding portion 331, but also achieve insulation protection to the binding portion 331. During the bending process of the display module 200, due to the influence of factors such as the bending degree and thickness, a step structure T will be formed at edges of the protective layer 332 and the binding portion 331 in the third direction Y2. In view of this, the embodiments of the present disclosure provide the dam structure 20 at this position, which helps to improve the manufacturing yield of the plastic frame 40. After insert molding, the dam structure 20 can also be separated, thereby reducing a space of the internal space of the display device 300 occupied by the dam structure 20.

The adhesion-reducing layer 34 can cover part of the binding portion 331 that extends beyond the protective portion in the third direction Y2, so that the adhesion-reducing layer 34 at least partially covers the step structure T, thereby satisfying the contact requirements between the adhesion-reducing layer 34 and the dam structure 20, and reducing the difficulty in separating the dam structure 20 from the display module 200.

In some embodiments, as shown in FIGS. 8-10, the composite functional layer 33 includes a support layer 333 provided on a side of the binding portion 331 facing towards the display portion 31, and in the third direction Y2, the support layer 333 extends beyond the binding portion 331. A projection of the adhesion-reducing layer 34 in the thickness direction X2 of the display portion 31 is located within the projection of the support layer 333 in the thickness direction X2 of the display portion 31.

The support layer 333 is a layer structure that supports the binding portion 331. Optionally, the support layer 333 can include steel. The support layer 333 is located on a side of the binding portion 331 facing towards the display portion 31, and in the third direction Y2, the support layer 333 will extend beyond the binding portion 331. In view of this, the support layer 333, the binding portion 331, and the protective layer 332 will form a two-step structure T at their edges in the third direction Y2.

In the embodiments of the present disclosure, the projection of the adhesion-reducing layer 34 in the thickness direction X2 of the display portion 31 is provided within the projection of the support layer 333 in the thickness direction X2 of the display portion 31, that is, the adhesion-reducing layer 34 will not extend beyond the support layer 333, thereby preventing a direct contact between the adhesion-reducing layer 34 and the display portion 31, reducing the difficulty in separating the dam structure 20 and the display module 200 and reducing the adverse effect of the adhesion-reducing layer 34 on the display portion 31.

In some embodiments, the material of the adhesion-reducing layer 34 includes at least one of silicon dioxide or silicone oil.

In the embodiments of the present disclosure, silicone oil has low surface tension, which enables it to spread on a solid surface and reduce surface energy of the material, while silicon dioxide can reduce surface energy of the material by a method such as modification. In view of this, by setting the material of the adhesion-reducing layer 34 to include at least one of silicon dioxide or silicone oil, the surface energy can be reduced, thereby reducing adhesion between the dam structure 20 and the display module 200, and reducing the difficulty in separating them.

In a third aspect, referring to FIG. 11, some embodiments of the present disclosure provide a display module 200, which includes a display portion 31, a cover plate 32, a binding portion 331, a protective layer 332, and an adhesive layer 36. The cover plate 32 is provided on a side of the display portion 31, the binding portion 331 is provided on a side of the display portion 31 away from the cover plate 32, the protective layer 332 is provided on a side of the binding portion 331 away from the display portion 31, and the binding portion 331 extends beyond the protective layer 332 in the third direction Y2 to form a step structure T. The thickness direction X2 of the display portion 31 intersects the third direction Y2. The adhesive layer 36 is partially provided between the binding portion 331 and the protective layer 332, and a part of the structure in the adhesive layer 36 is attached to the step structure T.

The adhesive layer 36 is a film structure for fixing the protective layer 332 and the binding portion 331. Optionally, the adhesive layer 36 includes optical adhesive. In the related art, a projection of an adhesive layer structure for bonding the binding portion 331 and the protective layer 332 in the thickness direction X2 of the display portion 31 usually does not extend beyond the projection of the protective layer 332 in the thickness direction X2 of the display portion 31.

However, in the embodiments of the present disclosure, the structure of the adhesive layer 36 is adjusted, and a part of the structure of the adhesive layer 36 can be attached to the step structure T, that is, the projection of the part of the structure of the adhesive layer 36 in the thickness direction X2 of the display portion 31 will extend beyond the projection of the protective layer 332 in the thickness direction X2 of the display portion 31, and at least a part of the step structure T is covered. In view of this, during the insert molding process, the adhesive layer 36 can play a role in blocking the air leakage channel, thereby improving the manufacturing reliability of the plastic frame 40 when the dam structure 20 is directly eliminated.

Therefore, the display device 300 manufactured using the display module 200 provided in the embodiments of the present disclosure can also eliminate the dam structure 20 while ensuring the structural reliability of the plastic frame 40. A thickness of the adhesive layer 36 is usually smaller than a thickness of the dam structure 20, so such design can also reduce the impact on the internal layout of the display device 300 and release the space of the whole device.

In some embodiments, as shown in FIG. 11, the adhesive layer 36 includes an overflow portion 361 attached to the step structure T. In the thickness direction X2 of the display portion 31, a size H1 of the binding portion 331 and a size H2 of the overflow portion 361 satisfy: 0.5H1 ≤ H2 ≤ 3H1. Optionally, H2 can be equal to one of 0.5H1, H1, 1.5H1, 2H1, and 3H1.

The overflow portion 361 is a part of the adhesive layer 36 that extends beyond the protective layer 332. In order to meet the formation requirements of the overflow portion 361, the adhesive layer 36 needs to be thickened. Therefore, the embodiments of the present disclosure set the size H2 of the overflow portion 361 to be no smaller than half of the size H1 of the binding portion 331, so as to meet the formation requirements of the overflow portion 361 while making the overflow portion 361 to better cover the step structure T, thereby improving the manufacturing yield of the plastic frame 40. At the same time, the embodiments of the present disclosure also set the size H2 of the overflow portion 361 to be no more than three times the size H1 of the binding portion 331, so as to reduce the space of the internal space of the display device 300 occupied by the overflow portion 361 to free up space for the entire device.

In a fourth aspect, referring to FIG. 12, some embodiments of the present disclosure provide a display device 300 manufacturing using the insert mold 100 provided in any of the above embodiments. The display device 300 includes a display module 200 and a plastic frame 40 provided on a periphery of the display module 200. The display device 300 does not include a dam structure 20.

It should be noted that the display device 300 provided in the embodiments of the present disclosure has the beneficial effects mentioned in any of the above embodiments of the insert mold 100, which can be referred to the description of the insert mold 100 for details, and will not be repeated in the embodiments of the present disclosure.

In combination with the foregoing content, it can be learned that, according to different actual needs, the display device 300 can include at least one of the adhesion-reducing layer 34 or the overflow portion 361, or the display device 300 can include neither the adhesion-reducing layer 34 nor the overflow portion 361, which is not limited to in the embodiments of the present disclosure.

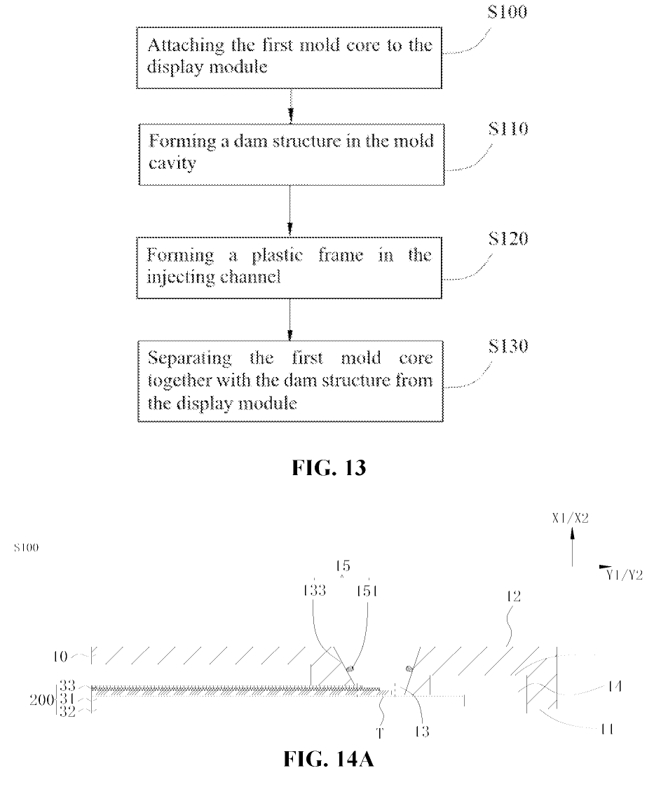

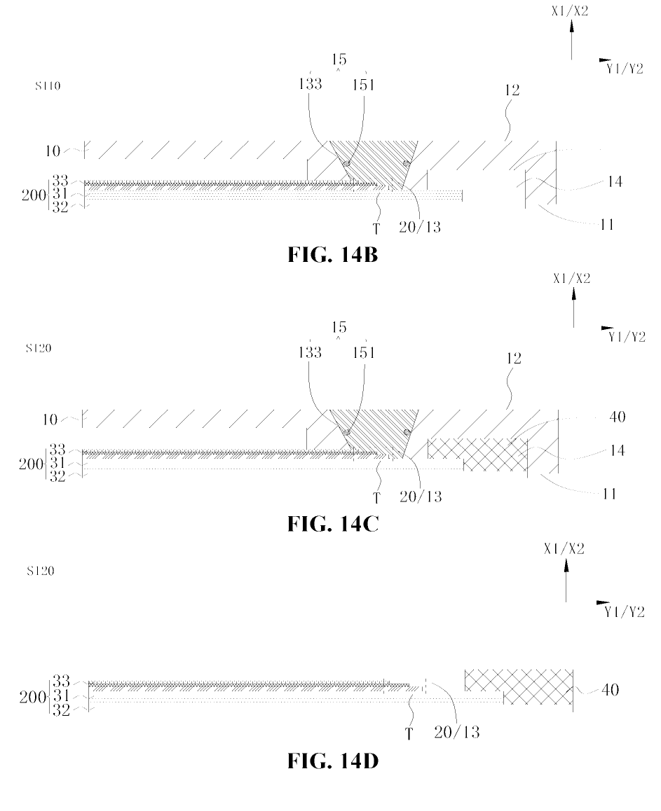

In a fifth aspect, referring to FIGS. 13 and 14, some embodiments of the present disclosure provide a method for manufacturing a display device 300 including steps S100 to S130.

At step S100, the first mold core is attached to the display module.

Referring to FIG. 14A, at step S100, the first mold core 10 is the first mold core 10 in the insert mold 100 provided in any of the above embodiments. Specifically, the first mold core 10 has the first surface 11 and the second surface 12 opposite to each other in the first direction X1. The first surface 11 is configured to contact the display module 200. The first mold core 10 includes the injection channel 14 and the cavity 13 that are recessed from the first surface 11. The injection channel 14 and the cavity 13 are separated from each other. The cavity 13 penetrates through the first mold core 10 along the first direction X1, and the first mold core 10 includes a fixing structure 15 in contact with the dam structure 20.

At step S110, a dam structure is formed in the cavity.

Referring to FIG. 14B, at step S110, the dam structure 20 and the first mold core 10 are not two independent structures, the formation of the dam structure 20 relies on the first mold core 10, and the size and the shape of the dam structure 20 are determined by the size and the shape of the cavity 13, respectively. Optionally, the size of the cavity 13 in the second direction Y1 gradually increases in the direction from the first surface 11 to the second surface 12.

At step S120, a plastic frame is formed in the injection channel.

Referring to FIG. 14C, at step S120, the plastic frame 40 is formed by casting resin into the injection channel 14. During this process, the dam structure 20 can block the air leakage channel at the step structure T, thereby improving the manufacturing reliability of the plastic frame 40.

At step S130, the first mold core together with the dam structure is separated from the display module.

Referring to FIG. 14D, at step S130, the fixing structure 15 in the first mold core 10 can take the dam structure 20 away from the display module 200, so that the dam structure 20 is not provided in the finally formed display device 300, thereby reducing the influence of the dam structure 20 on the internal layout of the display device 300 and releasing the space of the entire device.

Although the embodiments disclosed in the present disclosure are described as above, the contents described are only embodiments for facilitating the understanding of present disclosure and are not intended to limit the present disclosure. Any skilled in the art can make any modifications and changes in the form and details of implementation without departing from the spirit and scope disclosed in the present disclosure, but the protection scope of present disclosure shall still be defined by the scope defined in the attached claims.

The above are only specific implementations of the present disclosure. Those skilled in the art can clearly understand that for the convenience and simplicity of description, the replacement of other connection methods described above can refer to the corresponding process in the aforementioned method embodiment, which will not be repeated herein. It should be understood that the protection scope of the present disclosure is not limited to these description. Any skilled familiar with the art can easily think of various equivalent modifications or replacements within the technical scope disclosed in the present disclosure, and these modifications or replacements should fall within the protection scope of the present disclosure.

What is claimed is:

1. An insert mold for forming a plastic frame on a display module, the insert mold comprising:
a first mold, comprising a first mold core and a first mold base provided outside the first mold core, the first mold core having a first surface and a second surface opposite to each other in a first direction, the first surface being configured to be in contact with the display module, the first mold core comprising an injection channel, a cavity, and a fixing structure, the injection channel and the cavity being recessed from the first surface and separated from each other, the cavity being configured to form a dam structure through injection, and the fixing structure being configured to be in contact with the dam structure so that the insert mold is configured to take the dam structure away from the display module through the fixing structure.

2. The insert mold according to claim 1, wherein the cavity penetrates through the first mold core along the first direction.

3. The insert mold according to claim 2, wherein
the fixing structure comprises a side wall of the cavity; and
the cavity comprises a first sub-cavity and a second sub-cavity in communication with each other in the first direction, the second sub-cavity being located at a side of the first sub-cavity facing towards the second surface, and a maximum size of the second sub-cavity in a second direction perpendicular to the first direction being greater than a maximum size of the first sub-cavity in the second direction.

4. The insert mold according to claim 3, wherein a size of the cavity in the second direction gradually increases in a direction from the first surface to the second surface.

5. The insert mold according to claim 2, wherein the fixing structure comprises a protruding structure protrusively connected to a side wall of the cavity and configured to contact the dam structure.

6. The insert mold according to claim 5, wherein
the fixing structure comprises a plurality of the protruding structures, at least one of the plurality of the protruding structures each being configured to be in a plug-type fit with the dam structure; or
the protruding structure has a support surface away from the first surface, located in the cavity, and separated from the second surface in the first direction.

7. The insert mold according to claim 1, wherein the cavity is provided with a first opening away from the second surface in the first direction, a size L of the first opening in a second direction perpendicular to the first direction satisfying: 0.2 mm ≤ L ≤ 2 mm.

8. The insert mold according to claim 1, wherein the first surface comprises:
a first sub-surface located between the cavity and the injection channel, and
a second sub-surface located at a side of the cavity away from the injection channel and located at a side of the first sub-surface close to the second surface in the first direction.

9. The insert mold according to claim 1, further comprising:
a second mold, comprising a second mold core and a second mold base provided outside the second mold core.

10. A display module, attached to a plastic frame through an insert mold and comprising:
a display portion;
a cover plate provided on a side of the display portion;
a composite functional layer provided on a side of the display portion facing away from the cover plate;
an adhesion-reducing layer provided on a side of the composite functional layer away from the display portion and having adhesion smaller than adhesion of at least one layer of the composite functional layer,
wherein the insert mold comprises:
a first mold comprising a first mold core and a first mold base provided outside the first mold core, the first mold core having a first surface and a second surface opposite to each other in a first direction, the first surface being configured to be in contact with the display module, the first mold core comprising an injection channel, a cavity, and a fixing structure, the injection channel and the cavity being recessed from the first surface and separated from each other, the cavity being configured to form a dam structure through injection, and the fixing structure being configured to be in contact with the dam structure so that the insert mold is configured to take the dam structure away from the display module through the fixing structure.

11. The display module according to claim 10, wherein a surface of the composite functional layer away from the display portion forms a step structure at an edge region in a third direction intersecting a thickness direction of the display portion; and
the adhesion-reducing layer at least partially covers the step structure.

12. The display module according to claim 11, further comprising:
a bending portion,
wherein the composite functional layer comprises a binding portion and a protective layer provided on a side of the binding portion away from the display portion, the binding portion extending beyond the protective layer to form the step structure in the third direction; and
the binding portion is bent to a side of the display portion away from the cover plate through the bending portion, an end of the display portion in a fourth direction is connected to the bending portion, and the thickness direction of the display portion, the third direction, and the fourth direction intersect with each other.

13. The display module according to claim 12, wherein the composite functional layer further comprises a support layer provided on a side of the binding portion facing towards the display portion, the support layer extending beyond the binding portion in the third direction; and
a projection of the adhesion-reducing layer in the thickness direction of the display portion is located within a projection of the support layer in the thickness direction of the display portion.

14. The display module according to claim 10, wherein a material of the adhesion-reducing layer comprises at least one of silicon dioxide or silicone oil.

15. The display module according to claim 10, further comprising:
a second mold, comprising a second mold core and a second mold base provided outside the second mold core.

16. A display module, comprising:
a display portion;
a cover plate provided on a side of the display portion;
a binding portion provided on a side of the display portion away from the cover plate;
a protective layer provided on a side of the binding portion away from the display portion, the binding portion extending beyond the protective layer in a third direction to form a step structure, and a thickness direction of the display portion intersecting with the third direction;
an adhesive layer partially provided between the binding portion and the protective layer, a part of the adhesive layer being attached to the step structure.

17. The display module according to claim 16, wherein the adhesive layer comprises an overflow portion attached to the step structure, a size H1 of the binding portion in the thickness direction of the display portion and a size H2 of the overflow portion in the thickness direction of the display portion satisfying: 0.5H1 ≤ H2 ≤ 3H1.

18. A display device, manufactured using the insert mold according to claim 1, the display device comprising the display module and the plastic frame provided on a periphery of the display module.

19. A method for manufacturing a display device, the display device comprising a display module and a plastic frame provided on a periphery of the display module, and
the method comprising:
attaching the first mold core of the insert mold according to claim 1 to the display module, the cavity penetrating through the first mold core along the first direction;
forming the dam structure in the cavity;
forming the plastic frame in the injection channel; and
separating the first mold core together with the dam structure from the display module.
